(19) United States
(12) Patent Application Publication
(10) Pub. No.: US 2026/0252782 A1
(43) Pub. Date: Aug. 27, 2026

(54) PREDICTING CROSSTALK IN ELECTRICAL CIRCUITS USING ARTIFICIAL INTELLIGENCE

(71) Applicant: Texas Instruments Incorporated, Dallas, TX (US)

(72) Inventors: Katayoon Yahyaei, Addison, TX (US); Tapobrata Bandyopadhyay, Allen, TX (US); Snehamay Sinha, Plano, TX (US)

(21) Appl. No.: 19/309,252

(22) Filed: Aug. 25, 2025

Related U.S. Application Data
(60) Provisional application No. 63/761,485, filed on Feb. 21, 2025.

(51) Int. Cl. G06F 30/398; G06F 30/392

(52) U.S. Cl. CPC G06F 30/398; G06F 30/392

(57) ABSTRACT

An example apparatus includes interface circuitry configured to access at least one package file that describes a layout of circuitry; and processor circuitry coupled to the interface circuitry, the processor circuitry configured to execute or instantiate computer readable instructions to: run a simulation for the at least one package file to generate scattering parameter matrices; format the scattering parameter matrices; and generate a crosstalk prediction for the at least one package file at a package level by applying at least some of the formatted scattering parameter matrices to a model.

### RELATED APPLICATIONS

This application claims the benefit of U.S. Provisional Patent Application No. 63/761,485, filed Feb. 21, 2025, which is incorporated herein by reference in its entirety.

### TECHNICAL FIELD

This description relates generally to circuits, and, more particularly, to predicting crosstalk electrical circuits using artificial intelligence.

### BACKGROUND

Crosstalk in an electrical circuit refers to interference caused by unwanted transfer of signals between adjacent circuits or transmission lines. The interference occurs when the electromagnetic field generated by one signal is coupled with another, causing signal degradation or data corruption. Crosstalk-aggravated delay defects can be introduced by long parallel nets. As technology scales down in size, crosstalk-based defects become more significant.

### SUMMARY

An example of the description includes interface circuitry configured to access at least one package file that describes a layout of circuitry; and processor circuitry coupled to the interface circuitry, the processor circuitry configured to execute or instantiate computer readable instructions to: run a simulation for the at least one package file to generate scattering parameter matrices; format the scattering parameter matrices; and generate a crosstalk prediction for the at least one package file at a package level by applying at least some of the formatted scattering parameter matrices to a model. Other examples are described.

Example instructions cause processor circuitry to at least: run a simulation for at least one package file to generate scattering parameter matrices, the at least one package file describing a layout of circuitry; format the scattering parameter matrices; and generate a crosstalk prediction for the at least one package file at a package level by applying at least some of the formatted scattering parameter matrices to a model. Other examples are described.

An example method includes running, by executing an instruction with processor circuitry, a simulation for at least one package file to generate scattering parameter matrices, the at least one package file describing a layout of circuitry; formatting, by executing an instruction with the processor circuitry, the scattering parameter matrices; and generating, by executing an instruction with the processor circuitry, a crosstalk prediction for the at least one package file at a package level by applying at least some of the formatted scattering parameter matrices to a model. Other examples are described.

### BRIEF DESCRIPTION OF THE DRAWINGS

FIG. 1 is an environment to predict crosstalk in an integrated circuit package using artificial intelligence.

FIG. 2 is a block diagram of an example implementation of the script parsing circuitry of FIG. 1.

FIG. 3A illustrates an example conversion of scattering (S)-parameters into an S-parameter-based database of a pair of nets.

FIG. 3B illustrates an example conversion of S-parameters into a S-parameter-based database of superimposed crosstalk on nets.

FIG. 4 illustrates an example data flow corresponding to the generation of an AI-based model used to predict crosstalk.

FIGS. 5A and 5B illustrate a flowchart representative of example machine-readable instructions or operations that may be executed, instantiated, or performed by example programmable circuitry to implement the computing device of FIG. 1 to predict crosstalk in conjunction with examples disclosed herein.

FIG. 6 is a block diagram of an example processing platform including programmable circuitry structured to execute, instantiate, and/or perform the example machine-readable instructions and/or perform the example operations of FIGS. 5A-5B to implement the computing device of FIG. 1.

The same reference numbers or other reference designators are used in the drawings to designate the same or similar (functionally or structurally) features.

### DETAILED DESCRIPTION

The drawings are not necessarily to scale. Generally, the same reference numbers in the drawing(s) and this description refer to the same or like parts. Although the drawings show regions with clean lines and boundaries, some or all of these lines or boundaries may be idealized. In reality, the boundaries or lines may be unobservable, blended, or irregular.

As advancements in electrical systems such as integrated circuits, packages, system-on-chip, etc., and electrical components of such systems grow, new challenges in system co-design are discovered. For example, as advancements in Moore's law drive transistor miniaturization, the need for smaller, compact chips increases, intensifying the difficulties associated with system co-design. When designers create a design of an electrical system, some design optimization techniques utilize time-consuming and repetitive simulations to ensure that design specifications for the electrical system are met. For example, some design optimization techniques include time-consuming Electromagnetic Model (EM) extractions and simulations to evaluate crosstalk to determine if designs meet specifications. When such simulations determine that specifications are not satisfied, designers must modify the design and restart the entire process. Also, some design optimization techniques to verify design specifications of a design are becoming increasingly inadequate in addressing the complexities of modern package co-design, particularly with the emergence of advanced packaging technologies.

One portion of design optimization techniques includes determining whether the crosstalk of an IC package design is sufficiently low to not cause issues. Crosstalk in an electrical circuit refers to the unwanted transfer of signals between adjacent circuits or transmission lines. The smaller the crosstalk, the larger the signal integrity, which is a fundamental aspect of system co-design. As the size of electrical components decreases, traces (e.g., conductive paths used to transfer voltage, current, and/or signals) are positioned closer together, exacerbating crosstalk issues, particularly in high-speed and high-frequency systems.

Examples disclosed herein provide an automated solution to expedite the optimization/checking process, enabling designers to achieve compliant designs with fewer iterations and reduced effort. In particular examples disclosed herein, the automated solution is adapted to check the issue of crosstalk in electrical systems, such as integrated circuit (IC) packages, for high-speed double data rate (DDR) systems (HSDDR). Examples disclosed herein provide a framework for artificial intelligence (AI)-based crosstalk prediction in IC packages. Examples disclosed herein pre-process IC package files to obtain particular information that an AI-based model uses to predict crosstalk for an IC package design corresponding to the IC package files.

Also, examples disclosed herein determine the S-parameters of an IC package design based on the IC package files. S-parameters mathematically characterize signal interactions, describing signal propagation, reflection, and coupling between ports. Also, S-parameters measure signal transmission and coupling, offering insight into the strength of crosstalk. S-parameters capture non-monotonic variations in crosstalk across frequencies, enabling a comprehensive understanding of crosstalk behavior over a wide range. Examples disclosed herein can use the S-parameters as an input to an AI-based model to predict crosstalk. Examples disclosed herein significantly increase design optimization techniques.

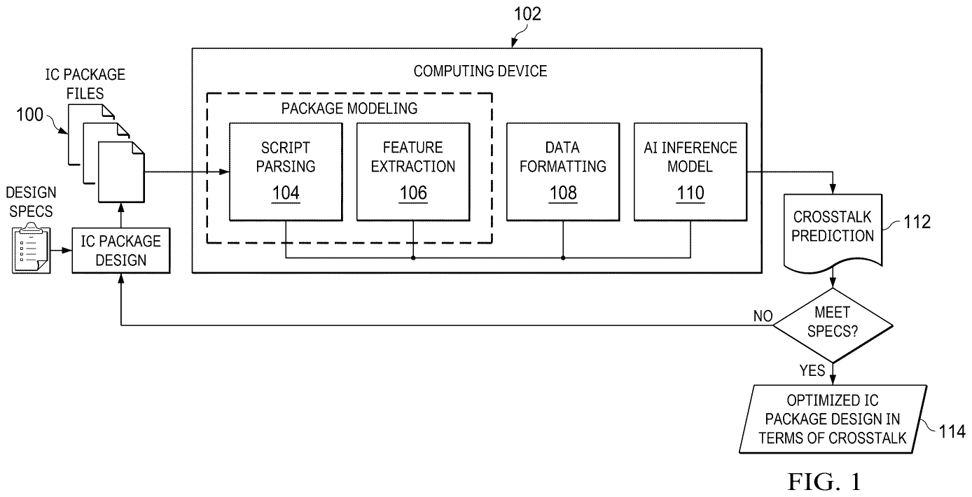

FIG. 1 is an environment to predict crosstalk in an integrated circuit package using artificial intelligence. FIG. 1 includes example IC package files 100, an example computing device 102 including example script parsing circuitry 104, example feature extraction circuitry 106, example data formatting circuitry 108, an example AI inference model 110, example crosstalk prediction 112, and an example output package design 114.

The computing device 102 of FIG. 1 may be instantiated (e.g., creating an instance of, bringing into being for any length of time, materializing, implementing, etc.) by programmable circuitry. For example, programmable circuitry may be implemented by a Central Processor Unit (CPU) executing first instructions, a field programmable gate array, a programmable logic device (PLD), a generic array logic (GAL) device, a programmable array logic (PAL) device, a complex programmable logic device (CPLD), a simple programmable logic device (SPLD), a microcontroller (MCU), a programmable system on chip (PSoC), etc. Additionally or alternatively, the computing device 102 of FIG. 1 may be instantiated (e.g., creating an instance of, bring into being for any length of time, materialize, implement, etc.) by (i) an Application Specific Integrated Circuit (ASIC) and/or (ii) a Field Programmable Gate Array (FPGA) (e.g., another form of programmable circuitry) structured and/or configured in response to execution of second instructions to perform operations corresponding to the first instructions. Computing device 102 can include a laptop computer, a desktop computer, and/or a server (e.g., part or all of a server rack). Computing device 102 is adapted and/or configurable to perform the operations described herein, including to run a simulation, format scattering parameter matrices, and generate a crosstalk prediction, among other operations. It should be understood that some or all of the circuitry of FIG. 1 may, thus, be instantiated at the same or different times. Some or all of the circuitry of FIG. 1 may be instantiated, for example, in one or more threads executing concurrently on hardware and/or in series on hardware. Moreover, in some examples, some or all of the circuitry of FIG. 1 may be implemented by microprocessor circuitry executing instructions and/or FPGA circuitry performing operations to implement one or more virtual machines and/or containers.

When a designer designs an IC package, the designer designs the IC package to achieve particular design specs or limitations. The design specs or limitations may provide guidelines for what a customer is expecting and/or needs within the IC package. Based on the design specs, the designer generates an IC package design that takes the form of the IC package files 100 that provide the information needed to generate and/or implement the IC package design. The IC package files 100 include information related to the design, structure, layout, etc. of the IC package design. As further described below, the computing device 102 processes the IC package files 100 to obtain structural and/or electrical information of the IC package design. The structural and/or electrical information may include net information, via information trace information, length of traces, coordinates of tracks, driver pin information, coordinates of components, pin type information, rise or fall time characteristics, trace width information, delay information, layer information, transmitter pin information, receiver pin information, trace information interconnectivity information, impedance information, resistance information, capacitance information, inductance information, etc., regarding one or more components and/or nets of the package design.

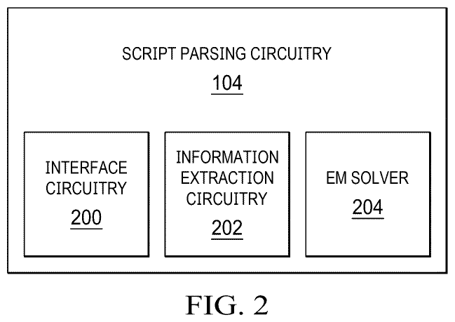

The script parsing circuitry 104 of the computing device 102 of FIG. 1 is adapted and/or configurable to parse through the IC package files 100 to determine relevant information to gather for inputting into the AI inference model 110. For example, the script parsing circuitry can parse the IC package files 100 to identify information related to the design, structure, layout, etc. of the IC package design, such as information related to nets, traces, length of traces, coordinates of tracks, interconnectivity information, impedance information, resistance information, capacitance information, inductance information, etc., regarding one or more components and/or nets of the package design. Also, the script parsing circuitry 104 can include an electromagnetic (EM) solver for determining S-parameters of the design based on the obtained information from the IC package files 100. The S-parameters correspond to an interaction between a first port and a second port of the circuitry when stimulated by a signal of a particular frequency. The script parsing circuitry 104 is further described below in conjunction with FIG. 2.

The feature extraction circuitry 106 of FIG. 1 is optional circuitry that is adapted and/or configurable to extract particular features of interest from the S-parameters determined by the script parsing circuitry 104. For example, although S-parameters provide useful insight into crosstalk, particular S-parameters may provide more insight than other S-parameters. Accordingly, the feature extraction circuitry 106 can extract or filter out the lower value S-parameters and generate a feature set of the more important features (e.g., S-parameters). For example, the feature extraction circuitry 106 may be adapted to generate a feature set that includes one or more S-parameters for the lowest frequency, one or more S-parameters for the Nyquist frequency, the minimum S-parameter, the maximum S-parameter, and/or the S-parameters for the highest frequency. However, the feature extraction circuitry 106 may be adapted to select different S-parameters to include in a feature set. In some examples, the feature set can include values that correspond to S-parameters buy are not necessarily equivalent to any S-parameter value. For example, if S-parameter values between a pair of nets in a frequency range are considered as a function (G(f)), the maximum of first derivative of that function can be a possible feature (max(dG/df)) in the feature set. The feature extraction circuitry 106 reduced feature set reduces computational complexity and may improve the accuracy of the AI-based model by providing the most important information, allowing the AI-based model to focus on the most relevant characteristics of the S-parameters. In some examples, the feature extraction circuitry 106 may include structural and/or electrical information in the feature set.

The data formatting circuitry 108 of FIG. 1 is adapted and/or configurable to format the electrical information, structural information, S-parameters, and/or feature set from the script parsing circuitry 104 and/or the feature extraction circuitry 106. For example, the data formatting circuitry 108 formats the obtained information to align with the requirements of the intended prediction task and the input specifications of the AI inference model 110. The data formatting circuitry 108 can format the information based on different factors, such as the type of package information being used, whether the AI inference model 110 is natural language processing (NLP)-based or not, and/or the specific prediction objective (e.g., where the AI-based model involves determining crosstalk value between one or more pairs of nets or the superimposed crosstalk on a single net caused by all other nets in the IC package). In some examples, the data formatting circuitry 108 of FIG. 1 formats the obtained information as a net sequence for IC package-level crosstalk. The net sequence format models the structural and electrical information from the driver to the receiver in each net, considering all components within the path, including vias and traces. An example form of the net sequence is shown in the below Equation 1, which corresponds to a vector including information about the driver pin (Pin_{Drv}), details of traces and vias in between the driver pin and a receiver pin (Trace, Via), and information about the receiver pin (Pin_{Rcv}).

$$Net Seq . = [ {Pin}_{Drv} , Trace , Via , {Pin}_{R c v} ] \qquad ( Equation 1 )$$

The below Equation 2 corresponds to example information related to the driver pin (Pin_{Drv}), including coordinates (Xₚᵢₙ, Yₚᵢₙ), pin type (Type) (e.g., input-only, output-only, bidirectional general purpose input output (GPIO)), load resistance (R_{load}), and rise or fall time (tᵣᵢₛₑ/t_{fall}) characteristics.

$${Pin}_{Drv} = [ {X}_{pin} , {Y}_{pin} , Type , {R}_{load} , {t}_{rise} / {t}_{fall} ] \qquad ( Equation 2 )$$

The below Equation 3 corresponds to example information related to trace segments (Trace), including trace segment length (L_{seg}), width (W_{seg}), delay (Dly_{seg}), the name of the layer it is located on (ID_{layer}), and the name of the net it belongs to (IDₙₑₜ).

$$Trace = [ {L}_{seg} , {W}_{seg} , Dl {y}_{seg} , {ID}_{layer} , {ID}_{net} ] \qquad ( Equation 3 )$$

The below Equation 4 corresponds to example information about vias (Via), such as their coordinates (Xᵥᵢₐ, Yᵥᵢₐ), diameter (Dimᵥᵢₐ), length (Lᵥᵢₐ), and the name of the net (IDₙₑₜ).

$$Via = [ {X}_{via} , {Y}_{via} , {Dim}_{via} , {L}_{via} , {ID}_{net} ] \qquad ( Equation 4 )$$

The below Equation 5 corresponds to example information related to the receiver pin (Pin_{Rcv}), including coordinates (Xₚᵢₙ, Yₚᵢₙ), pin type (Type), and output capacitance (Cₒᵤₜ).

$${Pin}_{Rcv} = [ {X}_{pin} , {Y}_{pin} , Type , {C}_{out} ] \qquad ( Equation 5 )$$

Although the data formatting circuitry 108 formats the obtained structural and/or electrical data based on the above-Equations 1-5, there may be other potential formats and conversion methods that may be applied depending on the specific requirements and/or constraints of the given application.

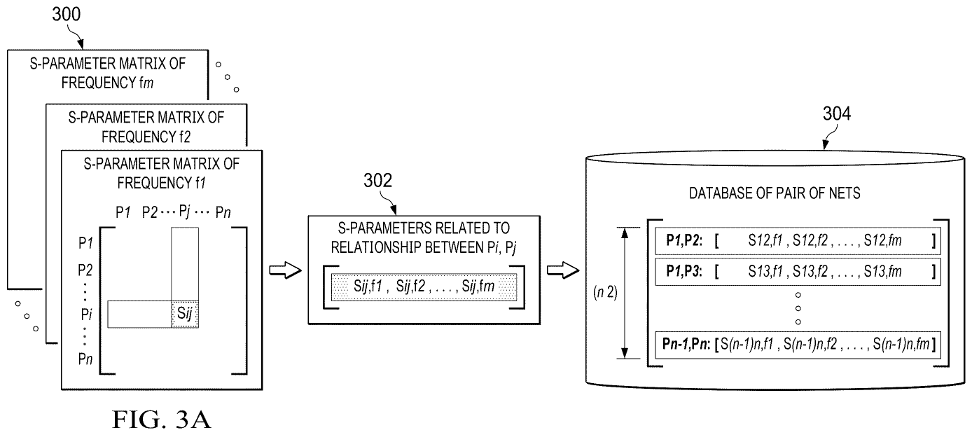

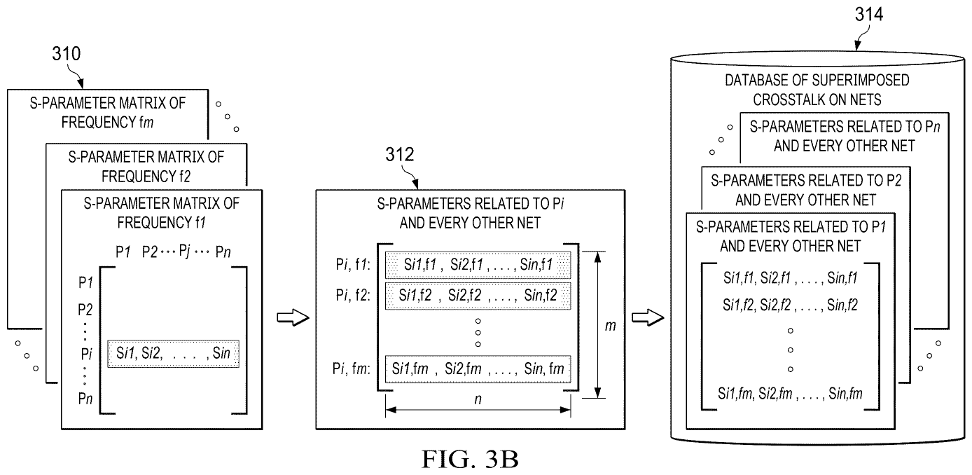

In some examples, the data formatting circuitry 108 of FIG. 1 formats the determined S-parameters into a particular format to be input into the AI inference model 110. The script parsing circuitry 104 generates the S-parameters, which are generally represented as m matrices of dimensions n×n, where m is the number of frequency points over which the analysis is swept, and n is the number of ports in the IC package design. The data formatting circuitry 108 can convert the m matrices into a database of pair of nets, which includes vectors representative of the S-parameters. The conversion of the S-parameters into the database of pair of nets is further described below in conjunction with FIG. 3A. In some examples, S-parameters can be determined for superimposed crosstalk, where each row of each matrix represents S-parameters related to a port and every other port in the IC package. In such examples, the data formatting circuitry 108 converts the S-parameter matrices into a database of superimposed crosstalk on nets, as further described below in conjunction with FIG. 3B.

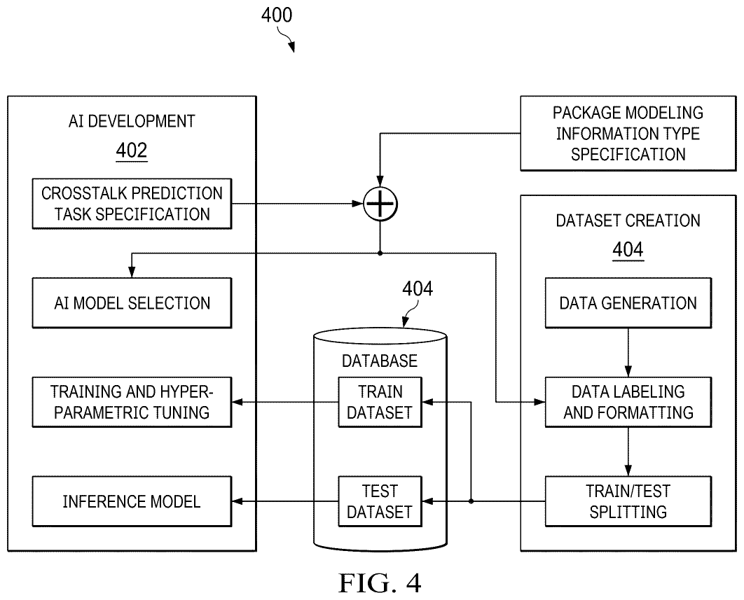

The AI inference model 110 is an AI-based model that has been trained to generate an output corresponding to an amount of crosstalk in an IC package design. The AI inference model 110 may be designed to output a crosstalk classification based on an input including one or more of the net sequences, the database of pair of nets, the database of superimposed crosstalk on nets, and/or the feature set. The AI inference model 110 can be customized based on variations in user needs, limitations/constraints of training data, etc., to reflect the desired accurate of a specific use case. The AI inference model 110 can generate a binary classification, a multi-class classification, or a regression classification. A binary classification is an output of 0 if the crosstalk is below a threshold and an output of 1 if the crosstalk is above the threshold (the threshold may be based on user preferences, demands of the system, design specifications, etc.). A binary classification requires the least number of resources, but provides the simplest, least precise output. A multi-class classification outputs different values for different crosstalk ranges. For example, 0 for no crosstalk, 1 for small crosstalk, 2 for medium crosstalk, 3 for large crosstalk, and 4 for significant crosstalk. However, the number of different values and their corresponding indication can be different. A multi-class classification is more precise than a binary classification but requires more resources (e.g., computational and training data). A regression classification predicts a continuous floating-point value for the crosstalk on each net, providing the most accurate predicted results but requiring the most resources (e.g., computational resources and training data). Further details related to an example selection of the AI inference model 110 are further described below in conjunction with FIG. 4. The AI inference model 110 generates a crosstalk prediction 112 based on the obtained input data that corresponds to the IC package design based on the IC package files 100. If a designer and/or the computing device 102 determines that the output crosstalk prediction 112 is satisfactory and/or meets the design specs, the designer/computing device 102 can select the IC package design as the optimized IC package design in terms of crosstalk. If the designer/computing device 102 determines that the output crosstalk prediction 112 is not satisfactory and/or does not meet the design specs, the designer/computing device 102 adjusts the IC package design to generate updated IC package files 100 that meet the design specs. For example, the designer/computing device can iteratively update the design until the design specs are met. For example, the designer/computing device can move/adjust the surrounding of the net with the highest superimpose crosstalk and use the AI inference model 110 to determine if the adjustment results in the design specs being met and/or whether the adjustment solved the high cross issues or not. In some examples, the AI inference model 110 may be implemented in a different computing device (e.g., in a server, an edge-based device, a cloud-based device, etc.). In such examples, the computing device 102 may provide the input data using a network connection and obtain a result from the AI inference model 110 via the network connection.

FIG. 2 is a block diagram of an example implementation of the script parsing circuitry 104 of FIG. 1. The script parsing circuitry 104 of FIG. 2 may be instantiated (e.g., creating an instance of, bringing into being for any length of time, materializing, implementing, etc.) by programmable circuitry. For example, programmable circuitry may be implemented by a Central Processor Unit (CPU) executing first instructions, a field programmable gate array, a programmable logic device (PLD), a generic array logic (GAL) device, a programmable array logic (PAL) device, a complex programmable logic device (CPLD), a simple programmable logic device (SPLD), a microcontroller (MCU), a programmable system on chip (PSoC), etc. Additionally or alternatively, the script parsing circuitry 104 of FIG. 2 may be instantiated (e.g., creating an instance of, bring into being for any length of time, materialize, implement, etc.) by (i) an Application Specific Integrated Circuit (ASIC) and/or (ii) a Field Programmable Gate Array (FPGA) (e.g., another form of programmable circuitry) structured and/or configured in response to execution of second instructions to perform operations corresponding to the first instructions. It should be understood that some or all of the circuitry of FIG. 2 may, thus, be instantiated at the same or different times. Some or all of the circuitry of FIG. 2 may be instantiated, for example, in one or more threads executing concurrently on hardware and/or in series on hardware. Moreover, in some examples, some or all of the circuitry of FIG. 2 may be implemented by microprocessor circuitry executing instructions and/or FPGA circuitry performing operations to implement one or more virtual machines and/or containers. The script parsing circuitry 104 includes example interface circuitry 200, example information extraction circuitry 202, and an example EM solver 204.

The interface circuitry 200 of FIG. 2 obtains the IC package files 100 corresponding to an IC package design for an IC package. The information extraction circuitry 202 searches through the obtained IC package files 100 to extract structural information and/or electrical information needed to generate S-parameters, and/or to generate the net sequence corresponding to the above Equations 1-5. Structural information directly influences electromagnetic coupling between signal traces, vias, and return current paths, which impact signal integrity. Structural information may include coupling length, with longer parallel segments increasing crosstalk, and line spacing, where narrower gaps intensify capacitive and inductive coupling. The trace width and cross-sectional dimensions affect impedance and signal propagation, while the relative positions of signal lines, particularly parallel arrangements, contribute to interference. Vias, connecting traces across layers, and signal termination types, which influence reflections, also play significant roles. Electrical information influences signal propagation and coupling. The faster signal rise time increases energy at higher frequencies, leading to a higher knee frequency. Crosstalk typically worsens at higher frequencies. Thus, the increased energy coupling between signal traces further exacerbates crosstalk effects. Impedance mismatches, determined by trace geometry and dielectric properties, lead to reflections that exacerbate Inter-Symbol Interference (ISI). Mutual capacitance between traces causes near-end crosstalk (NEXT) by allowing voltage changes on one trace to influence the other. Mutual inductance generates far-end crosstalk (FEXT) by inducing unwanted voltages due to changing magnetic fields. Additionally, termination techniques and device characteristics, such as input capacitance and output impedance, influence signal integrity and coupling.

The EM solver 204 of FIG. 2 utilizes structural and/or electrical information from the IC package files 101 to generate S-parameters. Frequency-dependent information can be informative for accurate crosstalk analysis at the IC package level. For example, electromagnetic coupling and signal behavior vary with frequency. S-parameters mathematically characterize signal interactions, describing signal propagation, reflection, and coupling between ports. Additionally, S-parameters measure signal transmission and coupling, offering direct insights into the strength of crosstalk. Unlike single-frequency analysis, S-parameters capture non-monotonic variations in crosstalk across frequencies, enabling a comprehensive understanding of its behavior over a wide range. To generate the S-parameters, the EM solver 204 can simulate the physical structure of the IC package design based on interconnects, via, and other components analyze simulated electromagnetic behavior of the IC package layout to generate the S-parameters. The EM solver 204 can simulate an interaction between a first port and a second port of the circuitry when stimulated by a signal of a particular frequency. For example, the EM solver 204 can determine a reflection and transmission of a signal at different ports of the circuitry across a range of frequencies. The simulation is repeated for different sets of ports. The EM solver 204 extracts, or otherwise determines, the S-parameters from simulation results. The EM solver 204 can generate S-parameters based on interactions between two ports or based on a superimposed crosstalk based on all ports.

FIG. 3A illustrates an example conversion of example S-parameter matrices 300 into example S-parameter relations between ports 302 and then into an example S-parameter-based database of a pair of nets 304. As described above, the data formatting circuitry 108 can obtain the S-parameter matrices 300 from the EM solver 204 and convert the S-parameter matrices 300 into the S-parameter-based database of a pair of nets 304.

The S-parameter analysis is generally represented as an m matrix of size n×n, where m is the number of frequency points over which the analysis is swept, and n is the number of ports. The cell in row i and column j of each matrix (Sij) contains the S-parameter corresponding to the interaction between ports Pi and Pj. The data formatting circuitry 108 extracts and concatenates the Sij value from each matrix into a vector (e.g., the S-parameters related to the relation between ports Pi, Pj 302), representing the S-parameters associated with the net pair of Pi (victim) and Pj (aggressor). The data formatting circuitry 108 creates the database 304 for each package by concatenating all these vectors (e.g., the S-parameters related to the relation between Pi, Pj 302, and other ports) associated with every possible net pair in the IC package.

FIG. 3B illustrates an example conversion of example S-parameter matrices 310 into example S-parameter relations between ports 312 and then into an example S-parameter-based database of a pair of nets 314. As described above, the data formatting circuitry 108 can obtain the S-parameter matrices 300 from the EM solver 204 and convert the S-parameter matrices 300 into the S-parameter-based database of a pair of nets 304.

Row i in each matrix represents the S-parameters 310 related to port Pi and every other port in an IC package. The data formatting circuitry 108 consolidates the S-parameters 310 for a single net (one port) across all analyzed frequencies. The data formatting circuitry 108 concatenates the rows forming an m×n matrix, as shown in the S-parameter relations between ports 312. The data formatting circuitry 108 creates a matrix for each net in the system to ensure that the data is suitable for analyzing the total superimposed crosstalk on a single net. The database of superimposed crosstalk on nets 314 is the set or collection of matrices for each net in the system generated by the data formatting circuitry 108. The data formatting circuitry 108 may input the database 304 of FIG. 3A or the database 314 of FIG. 3B into the AI inference model 110 of FIG. 1. In some examples, the feature extraction circuitry 106 filters the database(s) 304, 314 to generate a feature set, and the feature set is applied as an input to the AI inference model 110. In some examples, the feature extraction circuitry 106 combines the S-parameter information and/or feature set with structural and/or electrical information and applies the combination of information as an input into the AI inference model 110.

FIG. 4 illustrates an example data flow 400 corresponding to the generation and training of the AI inference model 110 used to predict crosstalk. The data flow 400 includes example AI development 402 and example dataset creation 404.

Initially, package modeling information type (e.g., structural, electrical, and/or S-parameter) and crosstalk prediction task (e.g., binary, regression, etc.) are specified (e.g., by a user, a manufacturer, etc.). The combination of these two sets of information is used to guide the labeling and formatting of the generated data to generate training data, which was achieved using traditional methods of simulation and measuring crosstalk. For example, if the crosstalk prediction is a binary classification based on electrical properties, then data is obtained and/or generated that is labelled as having a satisfactory amount of crosstalk or as having too much crosstalk. The dataset undergoes train-test splitting, where the training data is utilized for training the AI model and fine-tuning its hyperparameters. Hyperparameters are configurable parameters that govern the learning process of a model but are not derived from the training data. In the case of an artificial neural network (ANN), examples of hyperparameters may include the learning rate, batch size, number of hidden layers, and neurons per layer, activation function, and dropout rate. The test data, in turn, is used to evaluate the performance of the trained inference model on unseen data. For example, test data labelled with an output classification is applied to the AI-based model. If the output classification of the AI inference model matches the labeled output classification, then the result is marked as accurate. If the output classification of the AI inference model mismatches the labelled output classification, then the result is marked as inaccurate. If the application of the test data to the AI inference model results in more than a threshold accuracy based on the number of inaccurate and accurate results, then the AI inference model is deployed and implemented in the computing device as the AI inference model 110. If the application of the test data to the AI inference model 110 results in less than the threshold accuracy, then the AI inference model 110 is further trained with additional training data.

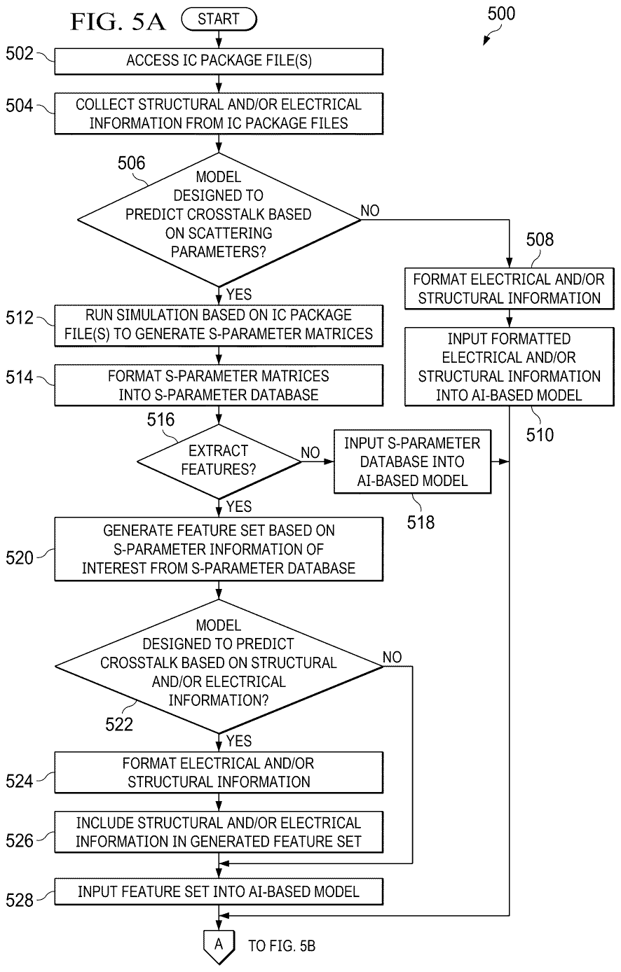

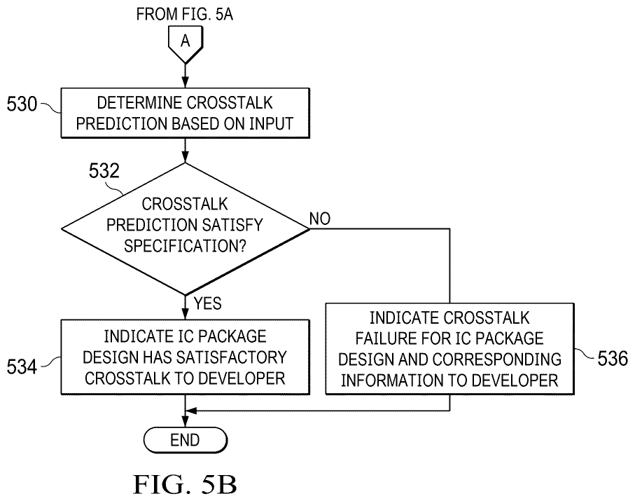

FIGS. 5A and 5B illustrate a flowchart representative of a method or operations 500 that may be executed or instantiated by the script parsing circuitry 104, the feature extraction circuitry 106, the data formatting circuitry, the AI inference model 110, the interface circuitry 200, the information extraction circuitry 202, and/or the EM solver of FIGS. 1 and/or 2 to generate the crosstalk prediction 112 based on IC package files 100 corresponding to an IC package design. For example, computing device 102 and its components may be adapted and/or configurable to perform some or all of the operations 500. The machine-readable instructions or the operations 500 of FIGS. 5A and 5B begin at block 502, at which the interface circuitry 200 of FIG. 2 accesses the IC package file(s) 100 of FIG. 1. The IC package file(s) 100 includes information related to an IC package design for an IC package based on a design specification.

At block 504, the information extraction circuitry 202 collects structural and/or electrical information from the IC package files. The structural and/or electrical information may include net information, via information trace information, length of traces, coordinates of tracks, driver pin information, coordinates of components, pin type information, rise or fall time characteristics, trace width information, delay information, layer information, transmitter pin information, receiver pin information, trace information interconnectivity information, impedance information, resistance information, capacitance information, inductance information, etc., regarding one or more components and/or nets of the package design. At block 506, the EM solver 204 determines if the AI inference model 110 is designed or trained to predict crosstalk based on scattering(S) parameters. If the EM solver 204 determines that the model is not trained to predict crosstalk based on S-parameter (block 506: NO), the data formatting circuitry 108 formats the electrical and/or structural information (block 508). For example, the data formatting circuitry 108 can generate one or more net sequence vector(s) using the electrical and/or structural information using the above Equations 1-5. At block 510, the data formatting circuitry 108 inputs the formatted electrical and/or structural information into the AI inference model 110, and control continues to block 530 of FIG. 5B.

If the EM solver 204 determines that the model is trained to predict crosstalk based on S-parameter (block 506: YES), the EM solver 204 runs simulations based on the information in the IC package files 100 to generate S-parameter matrices (block 512). As described above in conjunction with FIGS. 2, 3A, and 3B, the EM solver 204 can simulate the physical structure of the IC package design based on interconnects, via, and other components, analyze simulated electromagnetic behavior of the C package layout to generate the S-parameters. The EM solver 204 can simulate an interaction between a first port and a second port of the circuitry when stimulated by a signal of a particular frequency. The simulation is repeated for different sets of ports. The EM solver 204 extracts, or otherwise determines, the S-parameters from simulation results. The EM solver 204 can generate S-parameters based on interactions between two ports or based on a superimposed crosstalk based on all ports. At block 514, the data formatting circuitry 108 formats the S-parameter matrices into an S-parameter database (e.g., the S-parameter database 304 or 314, depending on how the AI inference model 110 is trained). Further description of the formatting of the S-parameter matrices into an S-parameter database is further described above in conjunction with FIGS. 3A and/or 3B.

At block 516, the feature extraction circuitry 106 determines if features are to be extracted from the S-parameter database (e.g., based on how the AI-based model was trained and/or user/manufacturer preferences). If the feature extraction circuitry 106 determines that features are not to be extracted (block 516: NO), the EM solver 204 inputs the S-parameter database into the AI inference model 110 (block 518), and control continues to block 530 of FIG. 5B. In some examples, the data formatting circuitry 108 may include electrical and/or structural information with the S-parameter database as an input into the AI inference model 110. If the feature extraction circuitry 106 determines that features are to be extracted (block 516: YES), the feature extraction circuitry 106 generates a feature set based on the S-parameter information of interest from the S-parameter database (block 520). For example, the feature extraction circuitry 106 may generate a feature set that includes one or more S-parameters for the lowest frequency, one or more S-parameters for the Nyquist frequency, the minimum S-parameter, the maximum S-parameter, and/or the S-parameters for the highest frequency, and/or any other S-parameter of interest.

At block 522, the data formatting circuitry 108 determines if the AI inference model 110 is designed/trained to predict crosstalk based on structural and/or electrical information, as well as the S-parameters. If the data formatting circuitry 108 determines that the AI inference model 110 is not trained to predict crosstalk based on structural and/or electrical information (block 522: NO), control continues to block 528. If the data formatting circuitry 108 determines that the AI inference model 110 is trained to predict crosstalk based on structural and/or electrical information (block 522: YES), the data formatting circuitry 108 formats the electrical and/or structural information (e.g., using the above Equations 1-5) (block 524). At block 526, the data formatting circuitry 108 includes the formatted electrical and/or structural information into the generated feature set. At block 528, the data formatting circuitry 108 inputs the feature set into the AI inference model 110.

At block 530 of FIG. 5B, the AI inference model 110 determines a crosstalk prediction based on the input. As described above in conjunction with FIGS. 1 and 4, the AI inference model 110 has been trained (e.g., using labelled training data) to generate a crosstalk prediction for an IC package design based on an input feature set and/or input structural, electrical, and/or S-parameter information. At block 532, the computing device 102 (e.g., hardware, software, firmware, a controller, a processor, etc. of the computing device 102) determines if the crosstalk prediction satisfies the design specification(s). For example, if the AI inference model 110 is binary, the computing device 102 determines that the crosstalk prediction satisfies the specification(s) if the output is a first value (e.g., 0) and determines that the crosstalk prediction does not satisfy the specification(s) if the output is a second value (e.g., 1). If the AI inference model 110 is multi-class or regression, the computing device 102 determines that the crosstalk prediction satisfies the specification(s) based on the comparison of the output of the AI inference model 110 to a threshold (e.g., defined by the specification(s), a designer, and/or a manufacturer).

If the computing device 102 determines that the crosstalk prediction satisfies the design specification(s) (block 532: YES), the computing device 102 indicates that the IC package design has satisfactory crosstalk to the developer (block 534). If the computing device 102 determines that the crosstalk prediction does not satisfy the design specification(s) (block 532: NO), the computing device 102 indicates the crosstalk failure for the IC package design to the developer and/or information related to the crosstalk failure (e.g., portions of the IC design that corresponds to high crosstalk and/or suggestions to lower crosstalk) (block 536). For example, the computing device 102 may include a user interface to display the results of the crosstalk prediction.

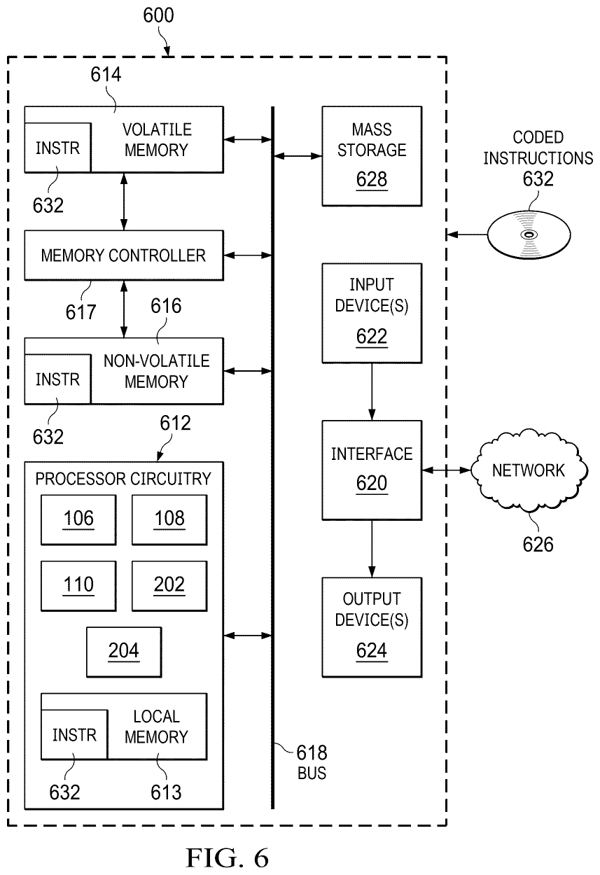

FIG. 6 is a block diagram of an example programmable circuitry platform 600 structured to one or a combination of execute or instantiate one or more of the example machine-readable instructions or the example operations of FIGS. 5A-5B to implement the [ER-Apparatus] of FIG. 1. The programmable circuitry platform 600 can be, for example, a server, a personal computer, a workstation, a self-learning machine (e.g., a neural network), a mobile device (e.g., a cell phone, a smart phone, a tablet such as an iPad™), a personal digital assistant (PDA), an Internet appliance, or any other type of computing or electronic device.

The programmable circuitry platform 600 of the illustrated example includes programmable circuitry 612. The programmable circuitry 612 of the illustrated example is hardware. For example, the programmable circuitry 612 can be implemented by one or more integrated circuits, logic circuits, FPGAs, microprocessors, CPUs, GPUs, DSPs, or microcontrollers from any desired family or manufacturer. The programmable circuitry 612 may be implemented by one or more semiconductor based (e.g., silicon based) devices. In this example, the programmable circuitry 612 implements some or all of the components of the computing device 102 such as the script parsing circuitry 104 (e.g., the information extraction circuitry 202 and the EM solver 204 of FIG. 2), the feature extraction circuitry 106, the data formatting circuitry 108, and the AI inference model 110 of FIG. 1.

The programmable circuitry 612 of the illustrated example includes a local memory 613 (e.g., a cache, registers, etc.). The programmable circuitry 612 of the illustrated example is in communication with main memory 614, 616, which includes a volatile memory 614 and a non-volatile memory 616, by a bus 618. The volatile memory 614 may be implemented by one or more Synchronous Dynamic Random Access Memory (SDRAM), Dynamic Random Access Memory (DRAM), RAMBUS® Dynamic Random Access Memory (RDRAM®), or any other type of RAM device. The non-volatile memory 616 may be implemented by one or a combination of flash memory or any other desired type of memory device. Access to the main memory 614, 616 of the illustrated example is controlled by a memory controller 617. In some examples, the memory controller 617 may be implemented by one or more integrated circuits, logic circuits, microcontrollers from any desired family or manufacturer, or any other type of circuitry to manage the flow of data going to and from the main memory 614, 616.

The programmable circuitry platform 600 of the illustrated example also includes interface circuitry 620. The interface circuitry 620 may be implemented by hardware in according to any type of interface standard, such as an Ethernet interface, a universal serial bus (USB) interface, a Bluetooth® interface, a near field communication (NFC) interface, a Peripheral Component Interconnect (PCI) interface, or a Peripheral Component Interconnect Express (PCIe) interface.

In the illustrated example, one or more input devices 622 are connected to the interface circuitry 620. The input device(s) 622 permit(s) a user (e.g., a human user, a machine user, etc.) to enter one of or a combination of data or commands into the programmable circuitry 612. The input device(s) 622 can be implemented by, for example, one of or a combination of an audio sensor, a microphone, a camera (still or video), a keyboard, a button, a mouse, a touchscreen, or a voice recognition system.

One or more output devices 624 are also connected to the interface circuitry 620 of the illustrated example. The output device(s) 624 can be implemented, for example, by one of or a combination of display devices (e.g., a light emitting diode (LED), an organic light emitting diode (OLED), a liquid crystal display (LCD), a cathode ray tube (CRT) display, an in-place switching (IPS) display, a touchscreen, etc.), etc. The interface circuitry 620 of the illustrated example, thus, includes one of or a combination of a graphics driver card, a graphics driver chip, or graphics processor circuitry such as a GPU.

The interface circuitry 620 of the illustrated example also includes a communication device such as one of or a combination of a transmitter, a receiver, a transceiver, a modem, a residential gateway, a wireless access point, or a network interface to facilitate exchange of data with external machines (e.g., computing devices of any kind) by a network 626. The communication can be by, for example, an Ethernet connection, a digital subscriber line (DSL) connection, a telephone line connection, a coaxial cable system, a satellite system, a beyond-line-of-sight wireless system, a line-of-sight wireless system, a cellular telephone system, an optical connection, etc.

The programmable circuitry platform 600 of the illustrated example also includes one or more mass storage discs or devices 628 to store one or more of firmware, software, or data. Examples of such mass storage discs or devices 628 include one or more magnetic storage devices (e.g., floppy disk, drives, HDDs, etc.), optical storage devices (e.g., Blu-ray disks, CDs, DVDs, etc.), RAID systems, or solid-state storage discs or devices such as flash memory devices and SSDs.

The machine-readable instructions 632, which may be implemented by the machine-readable instructions of FIGS. 5A and 5B, may be stored in one of or a combination of the mass storage device 628, in the volatile memory 614, in the non-volatile memory 616, or on at least one non-transitory computer readable storage medium such as a CD or DVD which may be removable. When executed, the machine-readable instructions 632 may cause the programmable circuitry platform 600 to perform some or all of the operations 500 shown in FIGS. 5A and 5B.

An example manner of implementing the computing device 102 is illustrated in FIG. 1, and an example manner of implementing the script parsing circuitry 104 is illustrated in FIG. 2. However, one or more of the elements, processes, and/or devices illustrated in FIGS. 1 and/or 2 may be combined, divided, rearranged, omitted, eliminated, and/or implemented in any other way.

Further, the computing device 102, the script parsing circuitry 104, the feature extraction circuitry 106, the data formatting circuitry 108, the AI inference model 110, the interface circuitry 200, the information extraction circuitry 202, and/or the EM solver 204 of FIGS. 1 and/or 2 may be implemented by hardware, software, firmware, and/or any combination of hardware, software, and/or firmware. As a result, for example, any of the computing device 102, the script parsing circuitry 104, the feature extraction circuitry 106, the data formatting circuitry 108, the AI inference model 110, the interface circuitry 200, the information extraction circuitry 202, and/or the EM solver 204 of FIGS. 1 and/or 2 could be implemented by one or more analog or digital circuit(s), logic circuits, programmable processor(s), programmable controller(s), graphics processing unit(s) (GPU(s)), digital signal processor(s) (DSP(s)), application specific integrated circuit(s) (ASIC(s)), programmable logic device(s) (PLD(s)) and/or field programmable logic device(s) (FPLD(s)).

When reading any of the apparatus or system claims of this patent to cover a purely software and/or firmware implementation, at least one of the computing device 102, the script parsing circuitry 104, the feature extraction circuitry 106, the data formatting circuitry 108, the AI inference model 110, the interface circuitry 200, the information extraction circuitry 202, and/or the EM solver 204 of FIGS. 1 and/or 2 is/are hereby expressly defined to include a non-transitory computer-readable storage device or storage disk such as a memory, a digital versatile disk (DVD), a compact disk (CD), a Blu-ray disk, etc., including the software and/or firmware. Further still, the computing device 102, the script parsing circuitry 104, the feature extraction circuitry 106, the data formatting circuitry 108, the AI inference model 110, the interface circuitry 200, the information extraction circuitry 202, and/or the EM solver 204 of FIGS. 1 and/or 2 may include one or more elements, processes, and/or devices in addition to, or instead of, those illustrated in FIGS. 1 and/or 2, and/or may include more than one of any or all of the illustrated elements, processes, and devices. As used herein, the phrase “in communication,” including variations thereof, encompasses direct communication and/or indirect communication through one or more intermediary components, and does not require direct physical (e.g., wired) communication and/or constant communication, but rather also includes selective communication at periodic intervals, scheduled intervals, aperiodic intervals, and/or one-time events.

A flowchart representative of example hardware logic, machine-readable instructions, hardware implemented state machines, and/or any combination thereof for implementing the computing device 102 of FIG. 1 is shown in FIG. 5A-5B. The machine-readable instructions may be one or more executable programs or portion(s) of an executable program for execution by a computer processor. The program may be embodied in software stored on a non-transitory computer readable storage medium such as a CD-ROM, a floppy disk, a hard drive, a DVD, a Blu-ray disk, or a memory associated with the processor, but the entire program and/or parts thereof could alternatively be executed by a device other than the processor and/or embodied in firmware or dedicated hardware.

Further, although the example program is described with reference to the flowchart illustrated in FIGS. 5A-5B, many other methods of implementing the computing device 102 may alternatively be used. For example, the order of execution of the blocks may be changed, and/or some of the blocks described may be changed, eliminated, or combined. Also or alternatively, any or all of the blocks may be implemented by one or more hardware circuits (e.g., discrete and/or integrated analog and/or digital circuitry, an FPGA, an ASIC, a comparator, an operational-amplifier (op-amp), a logic circuit, etc.) structured to perform the corresponding operation without executing software or firmware.

The machine-readable instructions described herein may be stored in one or more of a compressed format, an encrypted format, a fragmented format, a compiled format, an executable format, a packaged format, etc. Machine-readable instructions as described herein may be stored as data (e.g., portions of instructions, code, representations of code, etc.) that may be utilized to create, manufacture, and/or produce machine executable instructions. For example, the machine-readable instructions may be fragmented and stored on one or more storage devices and/or computing devices (e.g., servers). The machine-readable instructions may require one or more of installation, modification, adaptation, updating, combining, supplementing, configuring, decryption, decompression, unpacking, distribution, reassignment, compilation, etc. in order to make them directly readable, interpretable, and/or executable by a computing device and/or other machine. For example, the machine-readable instructions may be stored in multiple parts, which are individually compressed, encrypted, and stored on separate computing devices, in which the parts when decrypted, decompressed, and combined form a set of executable instructions that implement a program such as that described herein.

In another example, the machine-readable instructions may be stored in a state in which they may be read by a computer, but require addition of a library (e.g., a dynamic link library (DLL)), a software development kit (SDK), an application programming interface (API), etc. in order to execute the instructions on a particular computing device or other device. In another example, the machine-readable instructions may be configured (e.g., settings stored, data input, network addresses recorded, etc.) before the machine-readable instructions and/or the corresponding program(s) can be executed in whole or in part. As a result, the described machine-readable instructions and/or corresponding program(s) encompass such machine-readable instructions and/or program(s) regardless of the particular format or state of the machine-readable instructions and/or program(s) when stored or otherwise at rest or in transit.

The machine-readable instructions described herein can be represented by any past, present, or future instruction language, scripting language, programming language, etc. For example, the machine-readable instructions may be represented using any of the following languages: C, C++, Java, C #, Perl, Python, JavaScript, HyperText Markup Language (HTML), Structured Query Language (SQL), Swift, etc.

As mentioned above, the example process of FIG. 3 may be implemented using executable instructions (e.g., computer and/or machine-readable instructions) stored on a non-transitory computer and/or machine-readable medium such as a hard disk drive, a flash memory, a read-only memory, a compact disk, a digital versatile disk, a cache, a random-access memory and/or any other storage device or storage disk in which information is stored for any duration (e.g., for extended time periods, permanently, for brief instances, for temporarily buffering, and/or for caching of the information). As used herein, the term non-transitory computer readable medium is expressly defined to include any type of computer readable storage device and/or storage disk and to exclude propagating signals and to exclude transmission media.

Although certain example methods, apparatus and articles of manufacture have been described herein, the scope of coverage of this patent is not limited thereto. On the contrary, this patent covers all methods, apparatus and articles of manufacture fairly falling within the scope of the claims of this patent.

Descriptors “first,” “second,” “third,” etc. are used herein when identifying multiple elements or components which may be referred to separately. Unless otherwise specified or known based on their context of use, such descriptors do not impute any meaning of priority, physical order, or arrangement in a list, or ordering in time but are merely used as labels for referring to multiple elements or components separately for ease of understanding the described examples. In some examples, the descriptor “first” may be used to refer to an element in the detailed description, while the same element may be referred to in a claim with a different descriptor such as “second” or “third.” In such instances, such descriptors are used merely for ease of referencing multiple elements or components.

In the description and in the claims, the terms “including” and “having,” and variants thereof are to be inclusive in a manner similar to the term “comprising” unless otherwise noted. Unless otherwise stated, “about,” “approximately,” or “substantially” preceding a value means +/−10 percent of the stated value. In another example, “about,” “approximately,” or “substantially” preceding a value means +/−5 percent of the stated value. IN another example, “about,” “approximately,” or “substantially” preceding a value means +/−1 percent of the stated value.

The terms “couple,” “coupled,” “couples,” and variants thereof, as used herein, may cover connections, communications, or signal paths that enable a functional relationship consistent with this description. For example, if device A generates a signal to control device B to perform an action, if a first example device A is coupled to device B, or if a second example device A is coupled to device B through intervening component C if intervening component C does not substantially alter the functional relationship between device A and device B, such that device B is controlled by device A via the control signal generated by device A. Moreover, the terms “couple,” “coupled,” “couples,” or variants thereof, includes an indirect or direct electrical or mechanical connection.

A device that is “configured to” perform a task or function may be configured (e.g., programmed and/or hardwired) at a time of manufacturing by a manufacturer to perform the function and/or may be configurable (or re-configurable) by a user after manufacturing to perform the function and/or other additional or alternative functions. The configuring may be through firmware and/or software programming of the device, through a construction and/or layout of hardware components and interconnections of the device, or a combination thereof.

Although not all separately labeled in the FIGS. 1 and/or 2, components or elements of systems and circuits illustrated therein have one or more conductors or terminus that allow signals into and/or out of the components or elements. The conductors or terminus (or parts thereof) may be referred to herein as pins, pads, terminals (including input terminals, output terminals, reference terminals, and ground terminals, for instance), inputs, outputs, nodes, and interconnects.

As used herein, a “terminal” of a component, device, system, circuit, integrated circuit, or other electronic or semiconductor component, generally refers to a conductor such as a wire, trace, pin, pad, or other connector or interconnect that enables the component, device, system, etc., to electrically and/or mechanically connect to another component, device, system, etc. A terminal may be used, for instance, to receive or provide analog or digital electrical signals (or simply signals) or to electrically connect to a common or ground reference. Accordingly, an input terminal or input is used to receive a signal from another component, device, system, etc. An output terminal or output is used to provide a signal to another component, device, system, etc. Other terminals may be used to connect to a common, ground, or voltage reference, e.g., a reference terminal or ground terminal. A terminal of an IC or a PCB may also be referred to as a pin (a longitudinal conductor) or a pad (a planar conductor). A node refers to a point of connection or interconnection of two or more terminals. An example number of terminals and nodes may be shown. However, depending on a particular circuit or system topology, there may be more or fewer terminals and nodes. However, in some instances, “terminal,” “node,” “interconnect,” “pad,” and “pin” may be used interchangeably.

The term “or” or “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C.

Example methods, apparatus, systems, and articles of manufacture to facilitate access control in memory are described herein. Further examples and combinations thereof include the following: Example 1 includes an apparatus comprising interface circuitry configured to access at least one package file that describes a layout of circuitry, and processor circuitry coupled to the interface circuitry, the processor circuitry configured to execute or instantiate computer readable instructions to run a simulation for the at least one package file to generate scattering parameter matrices, format the scattering parameter matrices, and generate a crosstalk prediction for the at least one package file at a package level by applying at least some of the formatted scattering parameter matrices to a model.
Example 2 includes the apparatus of example 1, wherein the scattering parameter matrices include a scattering parameter corresponding to an interaction between a first port and a second port of the circuitry when stimulated by a signal of a particular frequency.
Example 3 includes the apparatus of example 1, wherein the processor circuitry is to run the simulation by determining a reflection and transmission of a signal at different ports of the circuitry across a range of frequencies.
Example 4 includes the apparatus of example 1, wherein the processor circuitry is to format the scattering parameter matrices by extracting and concatenating scattering parameters of the scattering parameter matrices into a vector, the vector including the scattering parameters across different frequencies for a first port and a second port of the circuitry.
Example 5 includes the apparatus of example 1, wherein the processor circuitry is to format the scattering parameter matrices by extracting and concatenating scattering parameters of the scattering parameter matrices into a matrix, the matrix including the scattering parameters related to a first port of the circuitry with respect to other ports of the circuitry across a range of frequencies.
Example 6 includes the apparatus of example 1, wherein the processor circuitry is to determine features of interest from the formatted scattering parameter matrices, and apply the features of interest to the model to generate the crosstalk prediction.
Example 7 includes the apparatus of example 6, wherein the features of interest correspond to at least one of a scattering parameter corresponding to a lowest frequency of the simulation, a scattering parameter corresponding to a highest frequency of the simulation, a scattering parameter corresponding to a Nyquist frequency, a minimum scattering parameter, or a maximum scattering parameter.
Example 8 includes the apparatus of example 6, wherein the processor circuitry is to add at least one of electrical information or structural information of the circuitry to the features of interest.
Example 9 includes the apparatus of example 8, wherein the at least one of the electrical information or the structural information includes at least one of driver pin information, trace segment information, via information, or receiver pin information.
Example 10 includes a non-transitory computer readable storage medium comprising instructions to cause processor circuitry to at least run a simulation for at least one package file to generate scattering parameter matrices, the at least one package file describing a layout of circuitry, format the scattering parameter matrices, and generate a crosstalk prediction for the at least one package file at a package level by applying at least some of the formatted scattering parameter matrices to a model.
Example 11 includes the non-transitory computer readable storage medium of example 10, wherein the scattering parameter matrices include a scattering parameter corresponding to an interaction between a first port and a second port of the circuitry when stimulated by a signal of a particular frequency.
Example 12 includes the non-transitory computer readable storage medium of example 10, wherein the instructions cause the processor circuitry to run the simulation by determining a reflection and transmission of a signal at different ports of the circuitry across a range of frequencies.
Example 13 includes the non-transitory computer readable storage medium of example 10, wherein the instructions cause the processor circuitry to format the scattering parameter matrices by extracting and concatenating scattering parameters of the scattering parameter matrices into a vector, the vector including the scattering parameters across different frequencies for a first port and a second port of the circuitry.
Example 14 includes the non-transitory computer readable storage medium of example 10, wherein the instructions cause the processor circuitry to format the scattering parameter matrices by extracting and concatenating scattering parameters of the scattering parameter matrices into a matrix, the matrix including the scattering parameters related to a first port of the circuitry with respect to other ports of the circuitry across a range of frequencies.
Example 15 includes the non-transitory computer readable storage medium of example 10, wherein the instructions cause the processor circuitry to determine features of interest from the formatted scattering parameter matrices, and apply the features of interest to the model to generate the crosstalk prediction.
Example 16 includes the non-transitory computer readable storage medium of example 15, wherein the features of interest correspond to at least one of a scattering parameter corresponding to a lowest frequency of the simulation, a scattering parameter corresponding to a highest frequency of the simulation, a scattering parameter corresponding to a Nyquist frequency, a minimum scattering parameter, or a maximum scattering parameter.
Example 17 includes the non-transitory computer readable storage medium of example 15, wherein the instructions cause the processor circuitry to add at least one of electrical information or structural information of the circuitry to the features of interest.
Example 18 includes the non-transitory computer readable storage medium of example 17, wherein the at least one of the electrical information or the structural information includes at least one of driver pin information, trace segment information, via information, or receiver pin information.
Example 19 includes a method comprising running, by executing an instruction with processor circuitry, a simulation for at least one package file to generate scattering parameter matrices, the at least one package file describing a layout of circuitry, formatting, by executing an instruction with the processor circuitry, the scattering parameter matrices, and generating, by executing an instruction with the processor circuitry, a crosstalk prediction for the at least one package file at a package level by applying at least some of the formatted scattering parameter matrices to a model.
Example 20 includes the method of example 19, wherein the scattering parameter matrices include a scattering parameter corresponding to an interaction between a first port and a second port of the circuitry when stimulated by a signal of a particular frequency.

Modifications are possible in the described examples, and other examples are possible, within the scope of the claims.

What is claimed is:

1. An apparatus comprising:
interface circuitry configured to access at least one package file that describes a layout of circuitry; and
processor circuitry coupled to the interface circuitry, the processor circuitry configured to execute or instantiate computer readable instructions to:
run a simulation for the at least one package file to generate scattering parameter matrices;
format the scattering parameter matrices; and
generate a crosstalk prediction for the at least one package file at a package level by applying at least some of the formatted scattering parameter matrices to a model.

2. The apparatus of claim 1, wherein the scattering parameter matrices include a scattering parameter corresponding to an interaction between a first port and a second port of the circuitry when stimulated by a signal of a particular frequency.

3. The apparatus of claim 1, wherein the processor circuitry is to run the simulation by determining a reflection and transmission of a signal at different ports of the circuitry across a range of frequencies.

4. The apparatus of claim 1, wherein the processor circuitry is to format the scattering parameter matrices by extracting and concatenating scattering parameters of the scattering parameter matrices into a vector, the vector including the scattering parameters across different frequencies for a first port and a second port of the circuitry.

5. The apparatus of claim 1, wherein the processor circuitry is to format the scattering parameter matrices by extracting and concatenating scattering parameters of the scattering parameter matrices into a matrix, the matrix including the scattering parameters related to a first port of the circuitry with respect to other ports of the circuitry across a range of frequencies.

6. The apparatus of claim 1, wherein the processor circuitry is to:
determine features of interest from the formatted scattering parameter matrices; and
apply the features of interest to the model to generate the crosstalk prediction.

7. The apparatus of claim 6, wherein the features of interest correspond to at least one of a scattering parameter corresponding to a lowest frequency of the simulation, a scattering parameter corresponding to a highest frequency of the simulation, a scattering parameter corresponding to a Nyquist frequency, a minimum scattering parameter, or a maximum scattering parameter.

8. The apparatus of claim 6, wherein the processor circuitry is to add at least one of electrical information or structural information of the circuitry to the features of interest.

9. The apparatus of claim 8, wherein the at least one of the electrical information or the structural information includes at least one of driver pin information, trace segment information, via information, or receiver pin information.

10. A non-transitory computer readable storage medium comprising instructions to cause processor circuitry to at least:
run a simulation for at least one package file to generate scattering parameter matrices, the at least one package file describing a layout of circuitry;
format the scattering parameter matrices; and
generate a crosstalk prediction for the at least one package file at a package level by applying at least some of the formatted scattering parameter matrices to a model.

11. The non-transitory computer readable storage medium of claim 10, wherein the scattering parameter matrices include a scattering parameter corresponding to an interaction between a first port and a second port of the circuitry when stimulated by a signal of a particular frequency.

12. The non-transitory computer readable storage medium of claim 10, wherein the instructions cause the processor circuitry to run the simulation by determining a reflection and transmission of a signal at different ports of the circuitry across a range of frequencies.

13. The non-transitory computer readable storage medium of claim 10, wherein the instructions cause the processor circuitry to format the scattering parameter matrices by extracting and concatenating scattering parameters of the scattering parameter matrices into a vector, the vector including the scattering parameters across different frequencies for a first port and a second port of the circuitry.

14. The non-transitory computer readable storage medium of claim 10, wherein the instructions cause the processor circuitry to format the scattering parameter matrices by extracting and concatenating scattering parameters of the scattering parameter matrices into a matrix, the matrix including the scattering parameters related to a first port of the circuitry with respect to other ports of the circuitry across a range of frequencies.

15. The non-transitory computer readable storage medium of claim 10, wherein the instructions cause the processor circuitry to:
determine features of interest from the formatted scattering parameter matrices; and
apply the features of interest to the model to generate the crosstalk prediction.

16. The non-transitory computer readable storage medium of claim 15, wherein the features of interest correspond to at least one of a scattering parameter corresponding to a lowest frequency of the simulation, a scattering parameter corresponding to a highest frequency of the simulation, a scattering parameter corresponding to a Nyquist frequency, a minimum scattering parameter, or a maximum scattering parameter.

17. The non-transitory computer readable storage medium of claim 15, wherein the instructions cause the processor circuitry to add at least one of electrical information or structural information of the circuitry to the features of interest.

18. The non-transitory computer readable storage medium of claim 17, wherein the at least one of the electrical information or the structural information includes at least one of driver pin information, trace segment information, via information, or receiver pin information.

19. A method comprising:
running a simulation for at least one package file to generate scattering parameter matrices, the at least one package file describing a layout of circuitry;
formatting the scattering parameter matrices; and
generating a crosstalk prediction for the at least one package file at a package level by applying at least some of the formatted scattering parameter matrices to a model.

20. The method of claim 19, wherein the scattering parameter matrices include a scattering parameter corresponding to an interaction between a first port and a second port of the circuitry when stimulated by a signal of a particular frequency.
